(19) United States
(12) Patent Application Publication
(10) Pub. No.: US 2021/0296216 A1
(43) Pub. Date: Sep. 23, 2021

(54) Semiconductor device, lead frame, and method for manufacturing semiconductor device

(71) Applicant: POWERTECH TECHNOLOGY INC., HSINCHU COUNTY (TW)

(72) Inventors: Toshitomo Fujiwara, HSINCHU COUNTY (TW); Fumitomo Watanabe, HSINCHU COUNTY (TW)

(21) Appl. No.: 16/820,748

(22) Filed: Mar. 17, 2020

(51) Int. Cl. H01L 23/495; H01L 23/31; H01L 21/48; H01L 21/56; H01L 21/78

(52) U.S. Cl. CPC H01L 23/49555; H01L 23/3114; H01L 23/49503; H01L 23/4952; H01L 21/78; H01L 21/4825; H01L 21/4842; H01L 21/561; H01L 21/565; H01L 23/49582

(57) ABSTRACT

A semiconductor device including a semiconductor chip, a plurality of leads and a sealing layer is disclosed. The lead includes a recess portion formed in the bottom surface at the outer side and a protruding portion formed in the top surface at the outer side. The protruding portion is formed to project from the top surface of the lead toward the sealing layer. A lead frame used in the semiconductor device and a method for manufacturing the semiconductor device are also disclosed.

### BACKGROUND OF THE INVENTION

### I. Field of the Invention

The disclosure relates to semiconductor devices. The disclosure also relates to lead frames used in semiconductor devices and methods for manufacturing semiconductor devices.

### 2. Description of the Prior Art

The quad flat no-lead (QFN) package is a lead-less semiconductor device widely applied in electronic packaging industry due to its small dimension, excellent thermal and electrical performance.

QFN package is usually designed with the die pad exposed in the bottom surface to create an efficient heat dissipation path to the mounting board of the electronic apparatus. To ensure that whether a successful solder joint is established between the QFN package and the mounting board, visual inspection is usually performed to examine the connection. However, the solder terminal is in the bottom surface of the QFN package and therefore the condition of connection cannot be easily confirmed.

To address the issue, efforts have been made to develop a QFN package with notch on the edge of the package body. The notch can be produced by either two-step sawing or half-etching to forma thinned portion in the bottom surface of the lead end. However, the shape and size of thinned portion produced by above methods are restricted to the thickness of the lead. It is therefore only small thinned portion can be formed and cannot serve either as satisfying visual indicator or as reliable solder joint. Moreover, the sawing method often results in burrs on the leads. Burrs are undesirable because they may accumulate within the notch of the leads and adversely affect solder mounting and joint reliability. Cost and labor are thus needed for burr removal. Besides, the etching method requires equipment for etching and cleaning, which increases the cost of operation and maintenance.

### SUMMARY OF THE INVENTION

According to one embodiment of the disclosure, a semiconductor device comprises a semiconductor chip, a plurality of leads provided around the semiconductor chip, and a sealing layer formed to cover the semiconductor chip and a part of the lead. Each of the leads includes a top surface, a bottom surface opposite to the top surface, an inner side near the semiconductor chip and an outer side opposite to the inner side. The lead is electrically connected to the semiconductor chip. The bottom surface and the outer side of the lead are exposed from the sealing layer. The lead includes a recess portion formed in the bottom surface at the outer side, and a protruding portion formed in the top surface at the outer side. The protruding portion is formed to project from the top surface of the lead toward the sealing layer.

According to the other embodiment, a lead frame comprises an outer frame, a central opening, a die pad disposed within the central opening, and a plurality of leads attached to the outer frame and extending toward the die pad. Each of the leads includes a top surface, a bottom surface opposite to the top surface, an inner side near the die pad and an outer side opposite to the inner side. The lead includes a recess portion formed in the bottom surface at the outer side and a protruding portion formed in the top surface at the outer side.

According to another embodiment, a method of manufacturing a semiconductor device is provided. The method comprises: providing a lead frame including a die pad and a plurality of leads, each of the leads including a top surface, a bottom surface opposite to the top surface, an inner side near the die pad and an outer side opposite to the inner side; loading the lead frame onto a lower mold, wherein the lower mold comprises a plurality of gaps disposed in spaced relation to each other; pressing the lead from a side opposite to the lower mold to form a recess portion and a protruding portion, wherein the protruding portion projects toward the gap of the lower mold; removing the lower mold from the lead frame; mounting a semiconductor chip on the die pad and electrically connecting the semiconductor chip to the lead; forming a sealing layer over the semiconductor chip and a part of the lead to form an encapsulated body, wherein a mold sheet is provided to adhere to the bottom surface of the lead; removing the mold sheet from the lead; plating the lead in the bottom surface; and singulating the encapsulated body along the recess portion, wherein the recess portion is sized and disposed such that a part of the recess portion remains after the singulating step.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1A is a schematic bottom view of a semiconductor device according to one embodiment of the present disclosure.

FIG. 1B is a schematic cross-sectional view taken along the line A-A′ of FIG. 1A.

FIG. 1C is a schematic side view of a semiconductor device according to one embodiment of the present disclosure.

FIG. 2A is a schematic top view of a lead frame according to the other embodiment of the present disclosure.

FIG. 2B is an enlargement of the encircled region X shown in FIG. 2A.

FIG. 3A is a schematic top view of a lead frame according to another embodiment of the present disclosure.

FIG. 3B is an enlargement of the encircled region X shown in FIG. 3A.

FIG. 4A is a schematic top view of a lead frame according to another embodiment of the present disclosure.

FIG. 4B is an enlargement of the encircled region X shown in FIG. 4A.

FIG. 5A is a schematic top view of a lead frame according to still another embodiment of the present disclosure.

FIG. 5B is an enlargement of the encircled region X shown in FIG. 5A.

FIG. 6 is a schematic top view of a lead frame according to a further embodiment of the present disclosure.

FIG. 7A-7I are cross-sectional views illustrating a sequence of steps that are used to manufacture the semiconductor device according to one embodiment of the present disclosure.

FIG. 8A is an enlargement of the encircled region Z shown in FIG. 7D.

FIG. 8B-8D show the exemplary shapes of the recess portion and the protruding portion according to other embodiments of the present disclosure.

FIG. 9A is a schematic cross-sectional view of a semiconductor device mounting on a mounting board according to one embodiment of the present disclosure.

FIG. 9B is a schematic side view of a semiconductor device mounting on a mounting board according to one embodiment of the present disclosure.

FIG. 10A-10F are cross-sectional views illustrating a sequence of steps that are used to manufacture the semiconductor device according to another embodiment of the present disclosure.

FIG. 11 is a schematic cross-sectional view of a semiconductor device manufactured according to the steps depicted in FIG. 10A-10F.

FIG. 12 is a schematic cross-sectional view of a semiconductor device according to still another embodiment of the present disclosure.

### DETAILED DESCRIPTION

Embodiments of the present disclosure will be described below with reference to the accompanying drawings as appropriate. Note that a semiconductor device, a lead frame or a method of manufacturing a semiconductor device to be mentioned later is intended to embody the technical concept of the present disclosure, and not to restrict the scope of the present disclosure to the following embodiments unless otherwise specified. The contents of one embodiment and one example of the present disclosure mentioned below can also be applied to other embodiments and examples. In some drawings, the sizes or positional relationships of members are emphasized to clarify the description below.

It should be noted that the term “comprise”, “comprising”, “include” or “including” does not exclude other elements or method-related steps, and that the term “a” or “an” should be understood as not excluding a plural number of elements or steps.

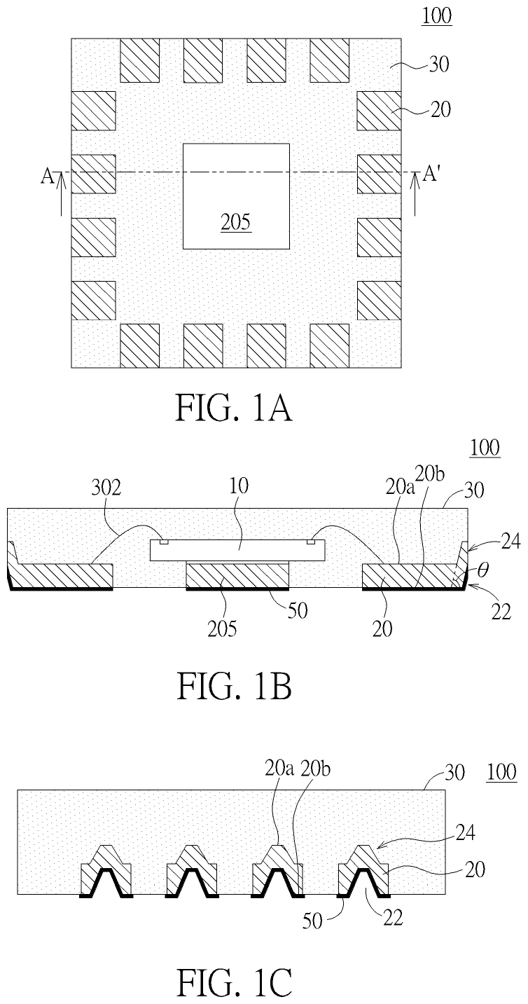

FIG. 1A shows a bottom view of a semiconductor device 100 according to one embodiment of the present disclosure. FIG. 1B shows a cross-sectional view taken along the line A-A′ of FIG. 1A. FIG. 1C shows a side view of the semiconductor device 100 of FIG. 1A.

As shown in FIG. 1A-1C, a semiconductor device 100 includes a semiconductor chip 10 mounting on a die pad 205, a plurality of leads 20 provided around the semiconductor chip 10, and a sealing layer 30. Each of the leads 20 includes a top surface 20a, a bottom surface 20b opposite to the top surface 20a, an inner side near the semiconductor chip 10 and an outer side opposite to the inner side. The lead 20 includes a positive electrode and a negative electrode (not shown). The semiconductor chip 10 is electrically connected to the lead 20. For wire-bond chip, the electrical connection can be made via bonding wires 302 as shown in FIG. 1B. For flip chip, the electrical connection between the semiconductor chip 10 and the lead 20 can be made via bumps 304 as shown in FIG. 12.

FIG. 1B depicts a sealing layer 30 which is formed to cover the semiconductor chip 10 and a part of the lead 20, leaving the bottom surface 20b and the outer side of the lead 20 exposed from the sealing layer 30. The lead 20 includes a recess portion 22 formed in the bottom surface 20b at the outer side and a protruding portion 24 formed in the top surface 20a at the outer side. The protruding portion 24 is formed to project from the top surface 20a of the lead 20 toward the sealing layer 30.

In this embodiment of the present disclosure, the outer side of the lead 20 indicates an area that is near a periphery of the semiconductor device 100 and includes the lead end. The inner side of the lead 20 indicates an area opposite to the outer side and is near the die pad 205 or the semiconductor chip 10.

As shown in FIG. 1B, the position of the recess portion 22 and the position of the protruding portion 24 may be corresponding to each other. Particularly, both of the recess portion 22 and the protruding portion 24 are formed at the outer side of the lead 20 such that the lead 20 at the outer side is taller than the lead 20 at the inner side. More particularly, the recess portion 22 and/or the protruding portion 24 may be formed to be exposed in a periphery of the semiconductor device 100.

The lead 20 may be formed to incline at the outer side such that the diameter of the recess portion 22 is reduced upward from the bottom surface 20b. The protruding portion 24 may also form an inclination angle θ less than 90° with respect to the bottom surface of the semiconductor device 100. The inclination angle θ can range, for example, from 45 to 63 degrees.

The recess portion 22 may be formed in a shape of arc, such as a part of a circle, or a part of an oval; or in a shape of polygon, such as triangle, trapezoid, pentagon, hexagon, heptagon, octagon or the like, as viewed from the side surface of the semiconductor device 100. The protruding portion 24 may be formed in a shape of arc, such as a part of a circle, or a part of an oval; or in a shape of polygon, such as triangle, trapezoid, pentagon, hexagon, heptagon, octagon or the like as viewed from the side surface of the semiconductor device 100. As an example shown in FIG. 1C, both of the recess portion 22 and the protruding portion 24 are formed in a shape of trapezoid as viewed from the side surface of the semiconductor device 100.

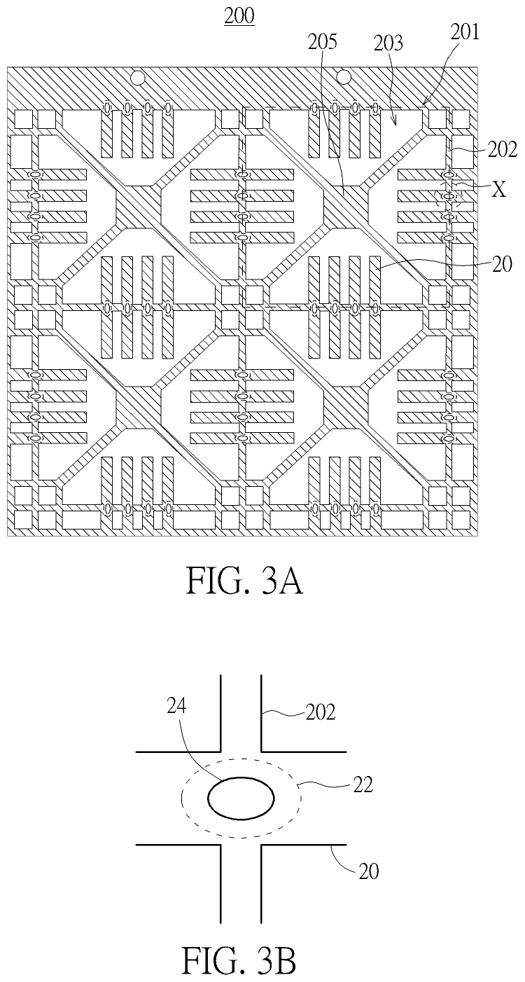

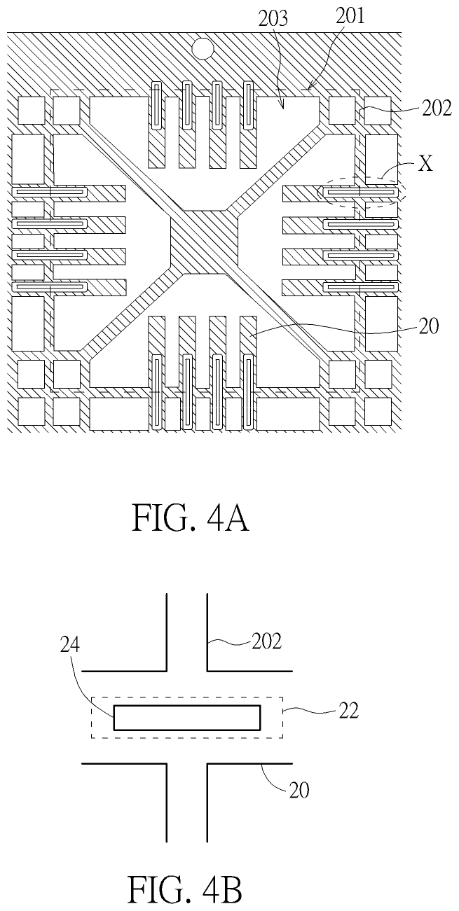

Also, the oval shape or the rectangular shape of the recess portion may be formed so that the longitudinal direction of the oval shape or the rectangular shape is arranged along an extending direction of the corresponding lead, as shown in FIG. 3A and FIG. 4A.

In addition, the width of the recess portion may be smaller than the width of the corresponding lead such that the opening of the recess portion can be covered by the mold sheet during encapsulating step so as to prevent the encapsulating material from flowing into the recess portion.

In some embodiments, the shape of the recess portion 22 and the shape of protruding portion 24 may be conformal. In other embodiments, the shape of the recess portion 22 and shape of the protruding portion 24 may be non-conformal.

In one embodiment of the present disclosure, the semiconductor device 100 may comprise a roughened surface (not shown) on the lead 20. Particularly, the roughened surface may be included in the top surface 20a of the lead 20. More particularly, the roughened surface may be included on the protruding portion 24 in the top surface 20a of the lead 20. The roughened surface on the lead 20 helps to increase the contacting area of the lead 20 with the sealing layer 30, thereby enhancing the adhesion strength between the lead 20 and the sealing layer 30 and preventing peeling within the semiconductor device 100.

In another embodiment, the semiconductor device 100 may comprise a plating layer 50 in the bottom surface 20b of the lead 20 and in the recess portion 22. The plating layer 50 may comprise a metal of lead, bismuth, tin, copper, silver, nickel, palladium, gold, or an alloy of the foregoing metals. The plating layer 50 helps to increase the solderability and conductivity of the lead 20.

As mentioned above, the recess portion in the prior art was made by two-step sawing or half-etching method to form a notch in the bottom surface of the lead end. The lead remains flat after two step-sawing or half-etching method, and the shape and size of the recess portion are restricted to the thickness of the lead.

Also, the sawing method generates burrs which accumulate within the notch and may adversely affect solder mounting and joint reliability.

Unlike the prior art, the recess portion 22 according to the present disclosure is a structural distortion made to the lead 20 without step-sawing or half-etching method. The structural distortion may be performed by a pressing tool, such as a punch, on the lead 20 to cause an elevated portion that constitutes a recess portion 22 formed in the bottom surface 20b at the outer side of the lead 20 and a protruding portion 24 formed in the top surface 20a of the lead 20. Because there is no need to cut off part of the lead to form a recess portion, the shape and size of the recess portion 22 of the present disclosure are not restricted to the thickness of the lead 20 and thus a wider or taller recess portion 22 can be formed.

The recess portion 22 of the present disclosure can be formed without the need of an etching and cleaning equipment. Further, since it is not necessary to use a dicing saw to form the recess portion 22, the occurrence of burrs can be reduced. Therefore, the labor and cost for removing burrs can be saved.

Accordingly, the recess portion 22 of the present disclosure increases the overall solderable area and can be easily observed from the side surface of the semiconductor device 100 and thus advantageously serves as a reliable solder joint and a visual indicator of soldering condition.

Furthermore, the protruding portion 24 formed to project from the top surface 20a of the lead 20 toward the sealing layer 30 provides an anchor effect between the lead 20 and the sealing layer 30, resulting in enhanced adhesion strength between the lead 20 and the sealing layer 30 and preventing peeling within the semiconductor device 100.

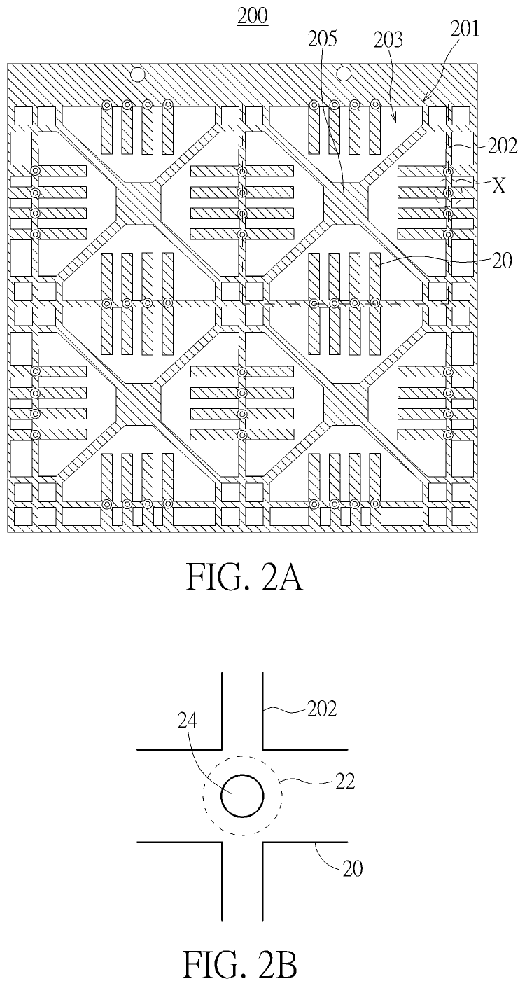

FIG. 2A shows a top plan view of a portion of a lead frame strip 200 according to the other embodiment of the present disclosure. The lead frame strip 200 includes a plurality of lead frames 201 (the square area enclosed by dotted line) arranged in at least one array. Each of the lead frames 201 comprises an outer frame 202, a central opening 203, a die pad 205 disposed within the central opening 203, and a plurality of leads 20 attached to the outer frame 202 and extending toward the die pad 205. Each of the leads 20 includes a top surface 20a, a bottom surface 20b opposite to the top surface 20a, an inner side near the die pad 205 and an outer side opposite to the inner side.

In this embodiment, the outer side of the lead 20 indicates an area that is near a periphery of the lead frame 201 and includes not only the lead end but also the outer frame 202.

FIG. 2B depicts an enlargement of the encircled region X shown in FIG. 2A. As seen in FIG. 2B, the lead 20 includes a protruding portion 24 (shown in solid line) formed in the top surface 20a at the outer side and a corresponding recess portion 22 (shown in dotted line) formed in the bottom surface 20b at the outer side. The recess portion 22 can be sized and disposed such that a part of the recess portion 22 remains after singulation. Particularly, the recess portion 22 and/or the protruding portion 24 can be sized and disposed such that a part of the recess portion 22 and a part of the protruding portion 24 remain after singulation.

In one embodiment, the recess portion 22 and the protruding portion 24 are formed as circular shape as viewed from the top of the lead frame 201 as shown in FIGS. 2A and 2B. In other embodiments, the shape of the recess portion 22 and the shape of the protruding portion 24 can also be formed as oval shape as illustrated in FIGS. 3A and 3B, or rectangular shape as illustrated in FIGS. 4A and 4B. In these embodiments, the recess portion 22 and the protruding portion 24 are disposed at the intersection of the lead 20 and the outer frame 202 to span across the intersection such that while a part of the recess portion 22 and a part of the protruding portion 24 will be removed after singulation, still a part of the recess portion 22 and a part of the protruding portion 24 will remain after singulation.

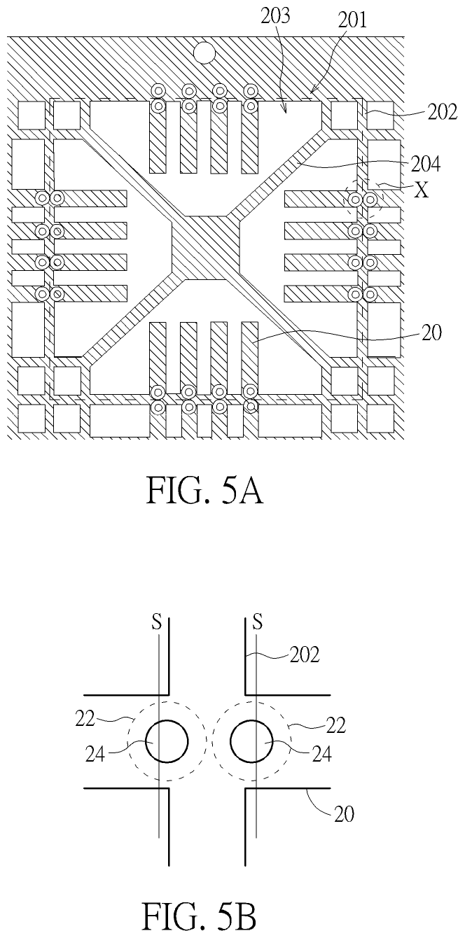

In the present disclosure, the number of the set of recess portion and protruding portion disposed at each intersection of the lead 20 and the outer frame 202 is not limited. For example, it can be one set of recess portion 22 and protruding portion 24 at each intersection of the lead 20 and the outer frame 202 as shown in FIGS. 2A, 3A, and 4A, or it can also be multiple sets of the recess portion 22 and the protruding portion 24 at each intersection of the lead 20 and the outer frame 202. For example, FIG. 5A shows two sets of the recess portion 22 and the protruding portion 24 disposed at the intersection of the lead 20 and the outer frame 202. FIG. 5B depicts an enlargement of the encircled region X shown in FIG. 5A. As shown in FIG. 5B, each set of the recess portion 22 and the protruding portion 24 are disposed and sized such that the recess portion 22 and the protruding portion 24 span across the singulation line S. Therefore, the part of the recess portion 22 and the part of the protruding portion between the two singulation lines S will be removed after singulation, whereas the part of the recess portion 22 and the part of the protruding portion 24 outside the two singulation lines S will remain after singulation.

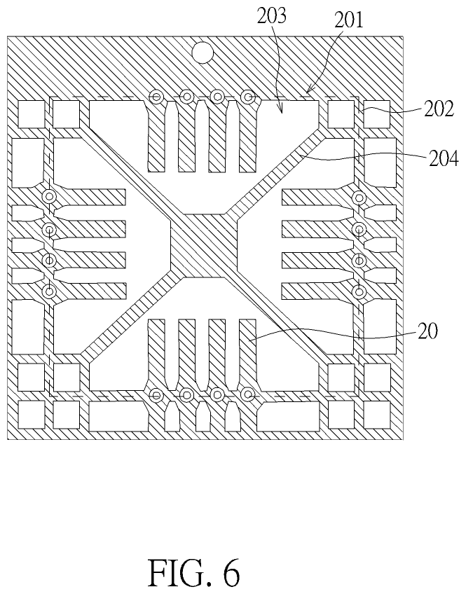

FIG. 6 illustrates a further embodiment of the lead frame according to the present disclosure. As shown in FIG. 6, the lead 20 at the outer side has a greater width than the lead 20 at the inner side so that larger room is provided at the intersection of the lead 20 and the outer frame 202 to accommodate a larger size or number of the recess portion 22 and protruding portion 24.

According to the lead frame 201 of present disclosure, the structure of the lead 20, the shape and the number of the recess portion 22 and the protruding portion 24 can be designed to better increase the overall solderable area and advantageously provide a reliable solder joint and a visual indicator of soldering condition.

Furthermore, the protruding portion 24 in the embodiment of the present disclosure provides an anchor effect, resulting in enhanced adhesion strength between the lead 20 and the sealing layer so as to prevent peeling within the semiconductor device.

In another embodiment, the lead frame 201 may comprise a roughened surface (not shown) on the lead 20. Particularly, the roughened surface may be included in the top surface 20a of the lead 20. More particularly, the roughened surface may be included in the protruding portion 24 in the top surface 20a of the lead 20. The roughened surface helps to increase the contacting area of the lead 20 with the sealing layer when applying the lead frame 201 to a semiconductor device, thereby enhancing the adhesion strength between the lead 20 and the sealing layer and preventing peeling within the semiconductor device 100.

According to another embodiment of the present disclosure, the lead frame 201 may comprise a plating layer (not shown) in the bottom surface of the lead 20 and in the recess portion 22. The plating layer may comprise a metal of lead, bismuth, tin, copper, silver, nickel, palladium, gold, or an alloy of the foregoing metals. The plating layer helps to increase the solderability and conductivity of the lead 20.

Further characteristics of the lead frame and the semiconductor device of the present disclosure will be described below in detail accompanying with the method of manufacturing the semiconductor device.

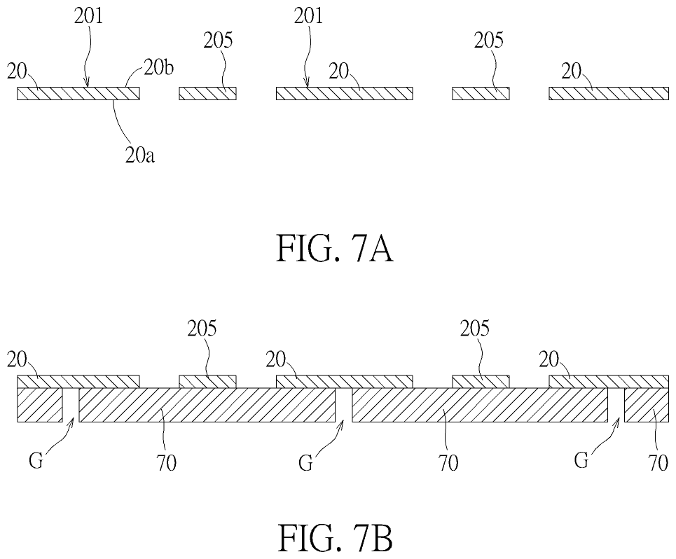

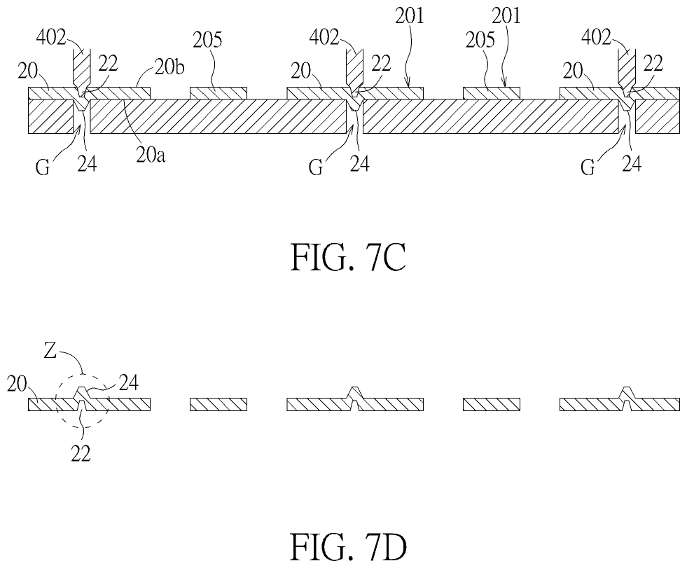

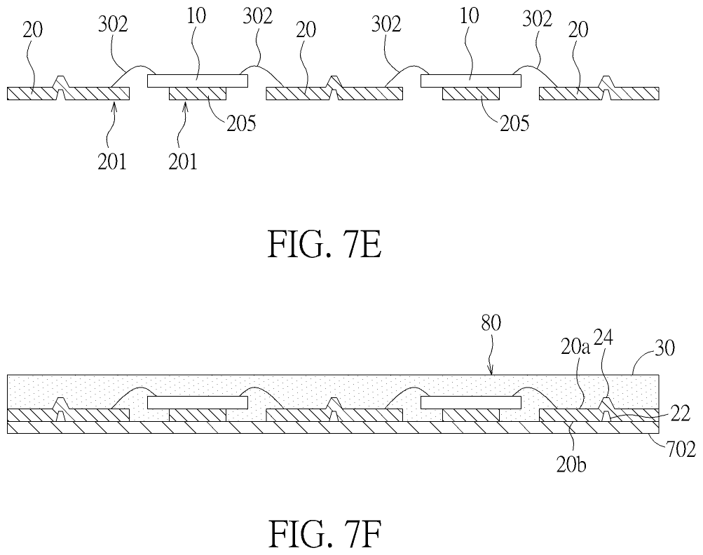

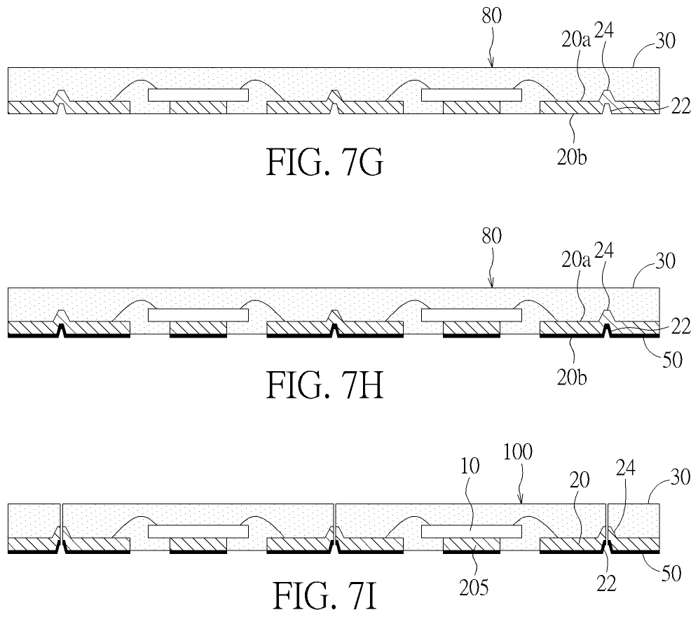

Referring now to FIG. 7A-7I, a cross-sectional view of a method for manufacturing the semiconductor device 100 according to the present disclosure is illustrated. The method comprises the following steps: providing a lead frame 201 including a die pad 205 and a plurality of leads 20 as shown in FIG. 7A, wherein each of the leads 20 includes a top surface 20a, a bottom surface 20b opposite to the top surface 20a, an inner side near the die pad 205 and an outer side opposite to the inner side; loading the lead frame 201 onto a lower mold 70 as shown in FIG. 7B, wherein the lower mold 70 comprises a plurality of gaps G disposed in spaced relation to each other; pressing the lead 20 from a side opposite to the lower mold 70 to form a recess portion 22 and a protruding portion 24 as shown in FIG. 7C, wherein the protruding portion 24 projects from the top surface 20a of the lead 20 toward the gap G of the lower mold 70; removing the lower mold 70 from the lead frame 201 as shown in FIG. 7D; mounting a semiconductor chip 10 on the die pad 205 and electrically connecting the semiconductor chip 10 to the lead 20 as shown in FIG. 7E; forming a sealing layer 30 over the semiconductor chip 10 and a part of the lead 20 to form an encapsulated body 80, wherein a mold sheet 702 is provided to adhere to the bottom surface 20b of the lead 20 as shown in FIG. 7F; removing the mold sheet 702 from the lead 20 and exposing the bottom surface 20b of the lead 20 as shown in FIG. 7G; plating the lead 20 to form a plating layer 50 in the bottom surface 20b as shown in FIG. 7H; and singulating the encapsulated body 80 along the recess portion 22 to form a semiconductor device 100 as shown in FIG. 7I, wherein the recess portion 22 is sized and disposed such that a part of the recess portion 22 remains after the singulating step.

According the embodiment of the present disclosure, the outer side of the lead 20 indicates an area that is near a periphery of the semiconductor device 100 and includes the lead end. The inner side of the lead 20 indicates an area opposite to the outer side and is near the die pad 205 or the semiconductor chip 10.

As shown in FIG. 7C, the recess portion 22, the protruding portion 24, and the gap G may be positioned corresponding to one another. Particularly, the space among each of the gaps G is arranged such that the recess portion 22 and the protruding portion 24 are to be formed at the outer side of the lead 20. More particularly, the space among each of the gaps G is arranged such that the recess portion 22 and/or the protruding portion 24 can be exposed in a periphery of the semiconductor device 100 after singulating step as depicted in FIG. 7I.

It is mentioned that the number of the recess portion 22 and protruding portion 24 formed by the method of the present disclosure is not limited. It can be one or multiple recess portion 22 and protruding portion 24. The space among each of the gaps G and the number of gaps G of the lower mold 70 can be arranged in accordance with the desired number and/or the desired position of the recess portion 22 and the protruding portion 24.

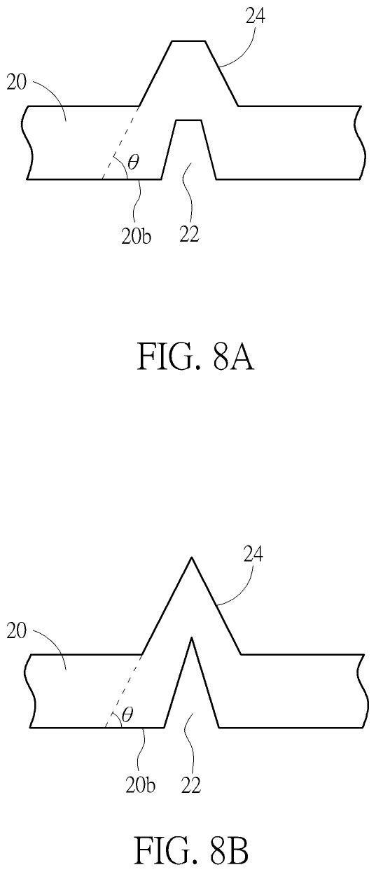

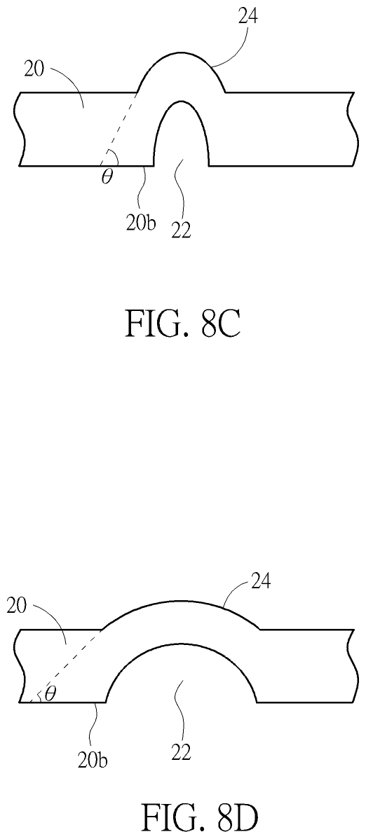

In the pressing step as shown in FIG. 7C, the lead 20 may be pressed to incline at the outer side such that the diameter of the recess portion 22 is reduced upward from the bottom surface 20b. FIG. 8A illustrates an enlargement of the encircled region Z shown in FIG. 7D. In FIG. 8A, the protruding portion 24 may be pressed to form an inclination angle θ less than 90° with respect to the bottom surface 20b. The inclination angle θ can range, for example, from 45 to 63 degrees. The pressing step may be performed by stamping or punching with a punch 402. The pressing step and the singulating step together will make the lead 20 at the outer side taller than the lead 20 at the inner side.

The shape of the recess portion 22 and the shape of the protruding portion 24 can be various and are not limited. Examples can be seen in FIG. 8A-8D. In some examples of the present embodiment, the recess portion 22 may be pressed to form a shape of polygon, such as triangle (see FIG. 8B), trapezoid (see FIG. 8A), pentagon, hexagon, heptagon, octagon or the like. In other examples of the present embodiment, the recess portion 22 may be pressed to form a shape of arc, such as a part of a circle (see FIG. 8C), or a part of an oval (see FIG. 8D). In some examples of the present embodiment, the protruding portion 24 may be pressed to form a shape of polygon, such as triangle (see FIG. 8B), trapezoid (see FIG. 8A), pentagon, hexagon, heptagon, octagon or the like. In other examples of the present embodiment, the protruding portion 24 may be pressed to form a shape of arc, such as a part of a circle (see FIG. 8C), or a part of an oval (see FIG. 8D).

In some embodiments, the shape of the recess portion 22 and the shape of protruding portion 24 may be arranged to be conformal. In other embodiments, the shape of the recess portion 22 and shape of the protruding portion 24 may be arranged to be non-conformal.

In still another embodiment, the method described above may further comprise a step of surface roughening (not shown) on the lead. Particularly, the surface roughening may be performed in the top surface 20a of the lead 20. More particularly, the surface roughening may be performed on the protruding portion 24 in the top surface 20a of the lead 20. The sequence of the surface roughening step may be arranged at any stage before the step of forming a sealing layer 30 over the semiconductor chip 10 and a part of the lead 20 to form an encapsulated body 80. The surface roughening step can also be arranged as a pre-treatment step before the step of providing a lead frame 201 including a die pad 205 and a plurality of leads 20. The surface roughening step may be performed, for example, by using plasma treatment. The roughened surface formed on the lead 20 increases the contacting area of the lead 20 with the sealing layer 30, thereby enhancing the adhesion strength between the lead 20 and the sealing layer 30 and preventing peeling within the semiconductor device 100.

In present disclosure, the plating layer 50 may be formed in the bottom surface 20b of the lead 20 and in the recess portion 22. The plating layer 50 may comprise a metal of lead, bismuth, tin, copper, silver, nickel, palladium, gold, or an alloy of the foregoing metals. The plating layer 50 is formed to help to increase the solderability and conductivity of the lead 20.

According to the present embodiment, the lead 20 is pressed to form a structural distortion. The structural distortion causes an elevated portion that constitutes a recess portion 22 formed in the bottom surface 20b at the outer side of the lead 20 and a protruding portion 24 formed in the top surface 20a of the lead 20. The protruding portion 24 is thus taller than the die pad 205 and the rest parts of the lead 20. Unlike the method in the prior art, there is no need to cut off part of the lead to form a recess portion. Thus, the shape and size of the recess portion 22 of the present disclosure are not restricted to the thickness of the lead 20 and therefore a wider or taller recess portion 22 can be formed. Accordingly, the recess portion 22 made by the method of present disclosure increases the overall solderable area and can be easily observed from the side surface of the semiconductor device 100 and thereby advantageously serves as a reliable solder joint and a visual indicator of soldering condition.

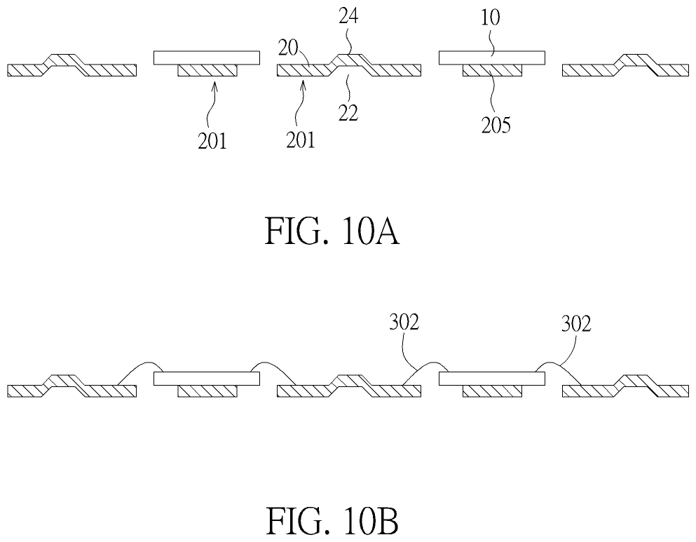

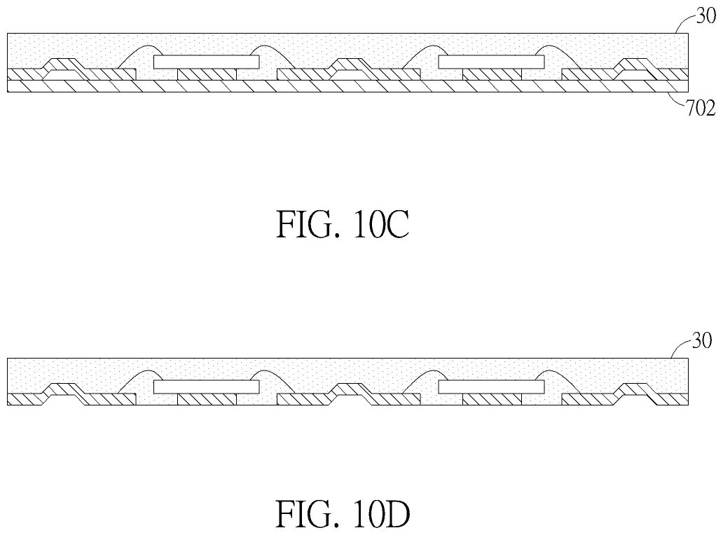

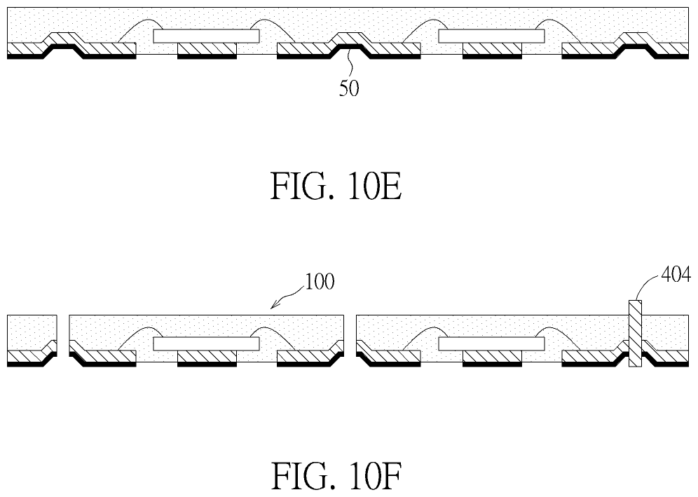

In present disclosure, the singulating step can be performed by sawing with a blade (shown as 404 in FIG. 10F) or punching with a punch (not shown) to separate the encapsulated body 80 into individual semiconductor devices 100. The width of the blade or punch can be adequately adjusted such that a part of the recess portion 22 and/or a part of the protruding portion 24 can be exposed in a periphery of the semiconductor device 100.

In present disclosure, the sealing layer 30 may be formed by encapsulating the encapsulating material over the semiconductor chip 10 and a part of the lead 20 to form an encapsulated body 80. The encapsulating material may be, for example, sealing resin. During encapsulating step, a mold sheet 702 is used to adhere to the bottom surface 20b of the lead 20 and cover the opening to recess portion 22 so as to prevent the encapsulating material or other impurities from flowing into the recess portion 22. It is noted that the width of the recess portion 22 may be formed smaller than the width of the corresponding lead 20 such that the opening of the recess portion can be fully covered by the mold sheet 702.

In another embodiment, the method may utilize a lead 20 which has a greater width at an outer side than at an inner side so that a larger space can be provided for the pressing step to form a larger size or number of the recess portion 22 and protruding portion 24.

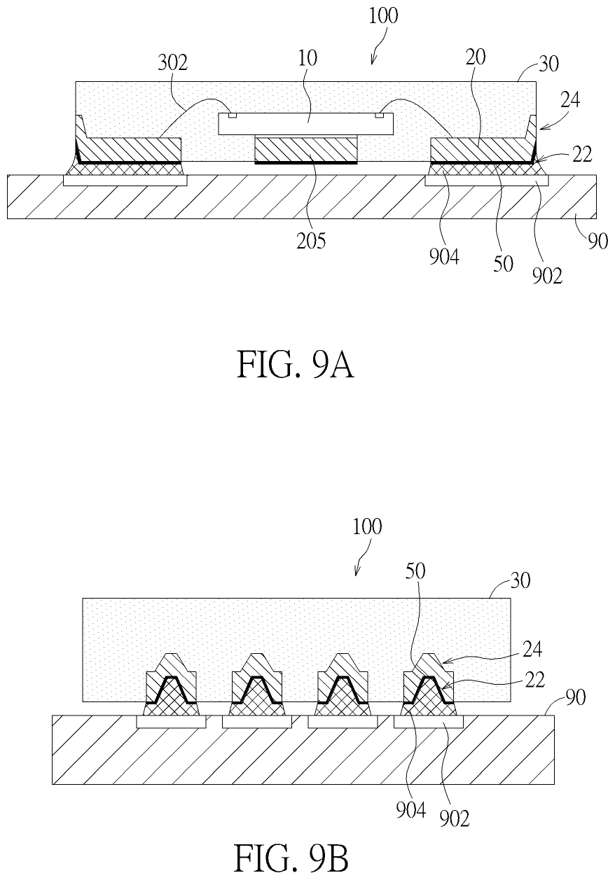

FIGS. 9A and 9B illustrate a cross-sectional view and a side view of a semiconductor device 100 mounting on a mounting board 90 according to one embodiment of the present disclosure. The semiconductor device 100 manufactured using the method described above has a recess portion 22 and a protruding portion 24 on the lead 20. The bottom surface 20b of the lead 20 and the recess portion 22 are covered with a plating layer 50. As shown in FIG. 9B, a solder 904 formed on the plating layer 50 extends up to the recess portion 22. As a successful connection between the semiconductor device 100 and the connection pad 902 of the mounting board 90, the solder 904 can be observed in the side surface of the semiconductor device 100 and serves as a visual indicator. For those solder 904 cannot be observed in the side surface of the semiconductor device 100, it means that the connection may fail and the semiconductor device 100 will be submitted to further check, rework or rejected. As can be seen from FIGS. 9A and 9B, the recess portion 22 effectively increases the overall solderable area and can be easily observed from the side surface of the semiconductor device 100. The recess portion 22 thus advantageously serves as a reliable solder joint and a visual indicator of soldering condition.

Furthermore, the protruding portion 24 formed to project toward the sealing layer 30 provides an anchor effect between the lead 20 and the sealing layer 30, resulting in enhanced adhesion strength between the lead 20 and the sealing layer 30 and preventing peeling within the semiconductor device 100.

As mentioned above, the shape and size of the recess portion 22 of the present disclosure are not restricted to the thickness of the lead 20 and thus a wider or taller recess portion 22 can be formed. FIG. 10A-10F show cross-sectional views of the method for manufacturing the semiconductor device according to another embodiment of the present disclosure. The detailed steps can also be referred to FIG. 7A-7I, with the difference that a wider recess portion 22 and protruding portion 24 are formed in this embodiment.

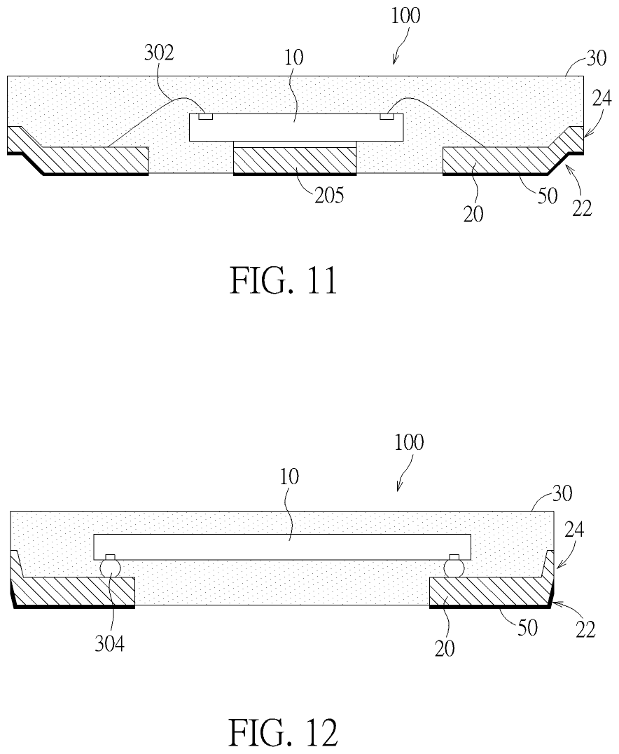

FIG. 11 illustrates a cross-sectional view of the semiconductor device of another embodiment. Compared with FIG. 1B, the recess portion 22 in FIG. 11 is wider in diameter and provides more room to accommodate the solder and thereby effectively increases the overall solderable area.

### [Semiconductor Device]

In the embodiments of the present disclosure, the semiconductor device 100 may be a quad flat-pack no-lead (QFN) package. Whereas the present disclosure can also be applicable equally to other flat-pack no-lead package, such as the dual flat-pack no-lead (DFN) package.

This disclosure provides exemplary embodiments of the invention. The scope of the invention is not limited by these exemplary embodiments. Numerous variations, modifications or equivalents, whether explicitly provided for by the specification or implied by the specification, such as variations, modifications or equivalents in structure, dimension, type of material and manufacturing process may be implemented by one of skill in the art in view of this disclosure.

What is claimed is:

1. A semiconductor device comprising:
a semiconductor chip;
a plurality of leads provided around the semiconductor chip, each of the leads including a top surface, a bottom surface opposite to the top surface, an inner side near the semiconductor chip and an outer side opposite to the inner side, and the lead electrically connected to the semiconductor chip; and
a sealing layer formed to cover the semiconductor chip and apart of the lead, leaving the bottom surface and the outer side of the lead exposed from the sealing layer,
wherein the lead includes a recess portion formed in the bottom surface at the outer side and a protruding portion formed in the top surface at the outer side, and the protruding portion is formed to project from the top surface of the lead toward the sealing layer.

2. The semiconductor device of claim 1, wherein a plating layer is formed in the bottom surface and in the recess portion of the lead.

3. The semiconductor device of claim 1, wherein the recess portion is formed in a shape of arc or polygon.

4. The semiconductor device of claim 1, wherein the lead at the outer side has a greater width than the lead at the inner side.

5. The semiconductor device of claim 1, wherein the recess portion is exposed in a periphery of the semiconductor device.

6. The semiconductor device of claim 1, wherein the protruding portion of the lead comprises a roughened surface.

7. The semiconductor device of claim 1, wherein the protruding portion forms an inclination angle less than 90° with respect to the bottom surface of the semiconductor device.

8. A lead frame comprising:
an outer frame;
a central opening;
a die pad disposed within the central opening; and
a plurality of leads attached to the outer frame and extending toward the die pad, each of the leads including a top surface, a bottom surface opposite to the top surface, an inner side near the die pad and an outer side opposite to the inner side,
wherein the lead includes a recess portion formed in the bottom surface at the outer side and a protruding portion formed in the top surface at the outer side.

9. The lead frame of claim 8, wherein the protruding portion is taller than the die pad.

10. The lead frame of claim 8, wherein the recess portion is formed in a shape of arc or polygon.

11. The lead frame of claim 8, wherein the lead at the outer side has a greater width than the lead at the inner side.

12. The lead frame of claim 8, wherein the recess portion is sized and disposed such that a part of the recess portion remains after singulation.

13. The lead frame of claim 8, wherein the protruding portion of the lead comprises a roughened surface.

14. The lead frame of claim 8, wherein the protruding portion forms an inclination angle less than 90° with respect to the bottom surface of the lead.

15. A method of manufacturing a semiconductor device, comprising:
providing a lead frame including a die pad and a plurality of leads, each of the leads including a top surface, a bottom surface opposite to the top surface, an inner side near the die pad and an outer side opposite to the inner side;
loading the lead frame onto a lower mold, wherein the lower mold comprises a plurality of gaps disposed in spaced relation to each other;
pressing the lead from a side opposite to the lower mold to form a recess portion and a protruding portion, wherein the protruding portion projects toward the gap of the lower mold;
removing the lower mold from the lead frame;
mounting a semiconductor chip on the die pad and electrically connecting the semiconductor chip to the lead;
forming a sealing layer over the semiconductor chip and a part of the lead to form an encapsulated body, wherein a mold sheet is provided to adhere to the bottom surface of the lead;
removing the mold sheet from the lead;
plating the lead in the bottom surface; and
singulating the encapsulated body along the recess portion, wherein the recess portion is sized and disposed such that apart of the recess portion remains after the singulating step.

16. The method of claim 15, wherein the protruding portion is taller than the die pad.

17. The method of claim 15, wherein the recess portion is formed in a shape of arc or polygon.

18. The method of claim 15, wherein the lead at the outer side has a greater width than the lead at the inner side.

19. The method of claim 15, wherein the protruding portion of the lead comprises a roughened surface.

20. The method of claim 15, wherein the protruding portion forms an inclination angle less than 90° with respect to the bottom surface of the lead.
